(19) United States
(12) Patent Application Publication
(10) Pub. No.: US 2009/0045515 A1
(43) Pub. Date: Feb. 19, 2009

(54) MONITORING THE MAGNETIC PROPERTIES OF A METAL LAYER DURING THE MANUFACTURE OF SEMICONDUCTOR DEVICES

(75) Inventors: David Gonzalez, JR., Plano, TX (US); Aaron Frank, Murphy, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 11/839,887

(22) Filed: Aug. 16, 2007

(51) Int. Cl. H01L 23/48; H01L 21/00

(52) U.S. Cl. 257/751; 438/10; 29/25.01; 257/E21.584

(57) ABSTRACT

A method for manufacturing a semiconductor device that comprises forming an interconnect structure in an insulating layer located on a semiconductor substrate. The method also comprises depositing a metal cap layer on the interconnect structure and measuring a magnetic property of the metal cap layer. The magnetic property is compared to a target magnetic property. If the measured magnetic property differs from the target magnetic property by a predefined amount, then one or both of an interconnect structure formation process or a metal cap layer deposition process are altered.

### TECHNICAL FIELD

The disclosure is directed, in general, to a method of manufacturing a semiconductor device that includes monitoring magnetic properties of a metal cap layer of the device, and devices manufactured thereby.

### BACKGROUND

Metal interconnect structures are used in today's semiconductor industry to interconnect active and passive device components (e.g., transistors and capacitors, respectively). As the dimensions of such device components are decreased with each new generation, so too are the dimensions of the metal interconnect structures. Metal interconnect structures are expected to tolerate increasingly higher current densities for new generations of smaller semiconductor devices.

### SUMMARY

The disclosure provides a method for manufacturing a semiconductor device. The method comprises forming an interconnect structure in an insulating layer located on a semiconductor substrate. The method also comprises depositing a metal cap layer on the interconnect structure and measuring a magnetic property of the metal cap layer. The magnetic property is compared to a target magnetic property. If the measured magnetic property differs from the target magnetic property by a predefined amount, then one or both of an interconnect structure formation process or a metal cap layer deposition process are altered.

Another embodiment of the method of manufacturing the device comprises depositing insulating layers on the substrate such that the transistors are covered by the insulating layers, and performing a damascene process to form copper interconnect structures in at least one of the insulating layers. Individual cobalt and phosphorus-containing cap layers are deposited on each of the copper interconnect structures using an electroless deposition process. A remnant magnetization of the cobalt and phosphorus-containing cap layers is measured. The measured remnant magnetization is compared to a target remnant magnetization. If the measured remnant magnetization differs from the target remnant magnetization by a predefined amount, then one or both of the damascene process or the electroless deposition process are altered. Alternatively, if the remnant magnetization does not differ from the target remnant magnetization by the predefined amount, then an additional insulating layer is deposited on the insulating layers.

The disclosure also provides a semiconductor device resulting from the above-described manufacture. The device comprises one or more transistors on or in the semiconductor substrate. The device further comprises an insulating layer on the substrate and over the transistors. There are interconnect structures in the insulating layer. Metal cap layers 310 are located on the interconnect structures and not on the insulating layer. At least one of the metal cap layers are formed by a process as described above.

### BRIEF DESCRIPTION OF DRAWINGS

The disclosure is described with reference to example embodiments and to accompanying drawings, wherein:

FIGS. 1 to 5 illustrate cross-section and plan views of selected steps in an example implementation of a method of manufacturing a semiconductor device of the disclosure.

### DETAILED DESCRIPTION

Electro-migration is expected to present challenges for the metal interconnect structure (e.g., line widths about 70 nm or less) and operating current densities (e.g., about 1×10⁶ Amps/cm² or higher) planned for the future generations of semiconductor devices. E.g., the electro-migration of copper atoms can cause voids to form in copper interconnect structures, or create short circuits between interconnect structures. Consequently, the yield and reliably of such semiconductor devices may be lower than desired.

The present disclosure describes the formation of metal cap layer on metal interconnect structures to deter the electro-migration of metal atoms of the interconnect structures. E.g., the metal cap layer blocks or caps the exit of copper atoms from a copper interconnect structure when a current is passed through the interconnect. It is desirable to deposit the metal cap layer using an electroless deposition process because this facilitates depositing the metal cap layer selectively on the metal interconnect structure. To function as an effective electro-migration barrier, however, the metal cap layer must be formed within narrow tolerances of thickness and physical properties. Unfortunately, the electroless deposition process is difficult to control. E.g., the concentrations of the components of the electroless deposition solution (e.g., a deposition bath) can rapidly change. This, in turn, can alter the physical properties and the deposition rate of the deposited metal cap layer.

The present disclosure benefits from the recognition that the magnetic properties of the metal cap layer can be used to monitor the efficacy of the electroless deposition process. Measuring the metal cap layer's magnetic properties as described herein allows the electroless deposition process to be monitored in near real-time and in situ. E.g., equipment needed to measure magnetic properties can be incorporated into an electroless deposition system, and the metal cap layer can be measured immediately after its fabrication. Moreover, the magnetic properties of the metal cap layers for each semiconductor device in a process flow can be measured, if desired.

As noted above, it is advantageous to measure the magnetic properties of the metal cap layer formed using electroless deposition processes because of difficulties in controlling this process. However, the metal cap layer, or other metal layers of the device, could be fabricated by other techniques, e.g., electrochemical deposition, ECD; physical vapor deposition, PVD; or chemical vapor deposition, CVD. The physical properties of such metal layers could also be assessed by measuring their magnetic properties as disclosed herein.

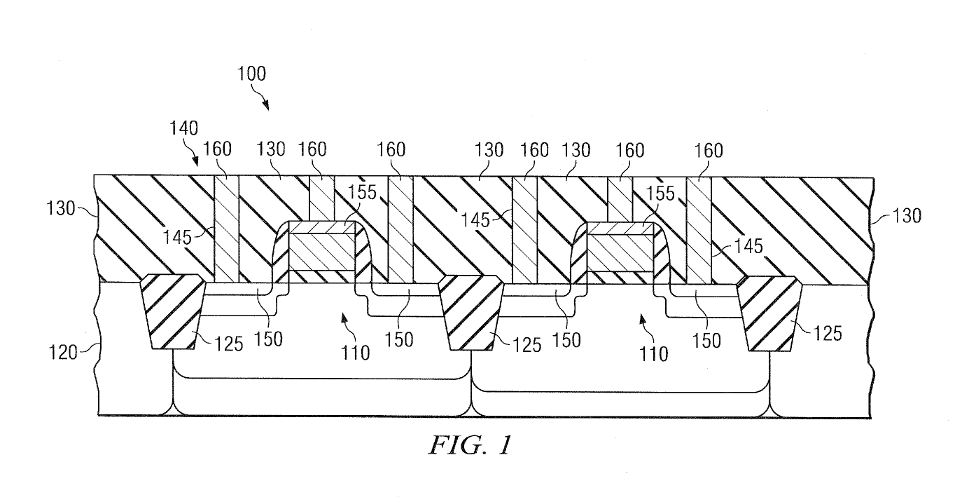

FIGS. 1 to 5 illustrate cross-section and plan views of selected steps in an example implementation of a method of manufacturing a semiconductor device 100 of the disclosure.

FIG. 1 shows a cross-sectional view of the device 100 after forming transistors 110 on a semiconductor substrate 120 (e.g., a silicon, silicon-on-insulator or other conventional semiconductor wafer substrate). Any conventional techniques can be used to form the transistors 110. The transistors 110 can include nMOS or pMOS transistors, Junction Field Effect transistors, NPN or PNP bipolar transistors, biCMOS transistors, or combinations thereof. Isolation structures 125 (e.g., shallow trench isolation structures or field oxide structure) in or on the substrate 120 can insulate the transistors 110 from each other or other active or passive components of the device 100.

FIG. 1 also shows the device 100 after forming an insulating layer, e.g., a pre-metal dielectric (PMD) layer 130, on the substrate 120 such that the transistors 110 are covered by the PMD layer 130. The PMD layer 130 can be composed of silicon dioxide, undoped or doped silicate glass, spin-on-glass, fluorosilicate glass or other low-dielectric constant material (e.g., a dielectric constant of less than about 4) and deposited by conventional procedures, such as chemical vapor deposition (CVD), or other conventional techniques. E.g., in some cases the PMD layer 130 includes silicon dioxide deposited from tetraethyl orthosilicate (TEOS) using CVD. In some cases, the PMD layer 130 includes a low-dielectric material deposited by spin coating, CVD or other conventional procedures.

As further shown in FIG. 1, contacts 140 can be formed in the PMD layer 130 to electrically couple the transistors 110 to each other, or to other components (e.g., resistors, capacitors) of the device 100. Dry or wet etch methods can be used to form contact openings 145 in the insulating layers 130, 135, such that the openings 145 expose electrodes of the transistors 110 (e.g., source and drain electrodes 150 or gate electrodes 155 of the transistors 110). The openings 145 can then be filled with a metal plug 160 (e.g., a tungsten plug) using PVD, CVD or other conventional techniques.

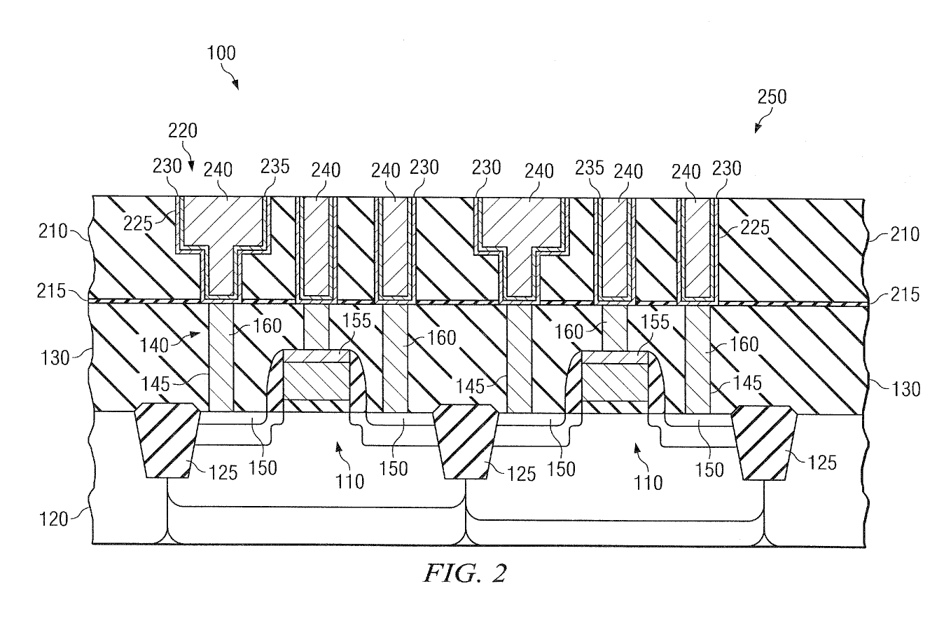

FIG. 2 shows the device 100 after forming another insulating layer, e.g., an inter dielectric layer (IDL) 210, on the substrate 120. The same materials and techniques as described to form the PMD layer 130 can be used to form the IDL 210. In some cases it is desirable for an etch stop layer 215 (e.g., SiC or other dielectric materials) to be formed (e.g., using plasma enhanced CVD) on the PMD layer 130 before forming the IDL 210.

FIG. 2 further shows the device 100, after forming an interconnect structure 220 (e.g., vias, lines, trenches) in the IDL 210. Again, the same materials and techniques as described to form the contacts 140 can be used to form the IDL 210. In some cases, interconnect openings 225 can be formed using a single or dual damascene process, or non-danascene interconnect formation process.

Forming the interconnect structure 220 by a damascene process can include conventional photolithographic and dry plasma etch techniques to form via and trench openings 225 in the IDL 210 down to the etch stop layer 215, followed by second dry etch to remove the etch stop layer 215 from the interconnect openings 225. The interconnect openings 225 can be conformally coated with one or more metal diffusion barrier or adhesion layers 230 (e.g., Ta, TaN, or both) and a copper seed layer 235 deposited using PVD or CVD. The openings 225 can then be filled with a copper layer 240 using ECD or electroless deposition, to form single or dual damascene copper interconnects 220. Forming the interconnect structure 220 can also remove portions of the deposited copper layer 240 laying outside of the interconnect openings 225 using conventional wet or dry etch processes or chemical mechanical polishing (CMP) processes. In some cases, the CMP process includes a polishing slurry that contain a metal corrosion inhibitor such as benzotriazole (BTA). The corrosion inhibitor helps to prevent corrosion of the interconnect structure's 220 surface 250 during and following the CMP step.

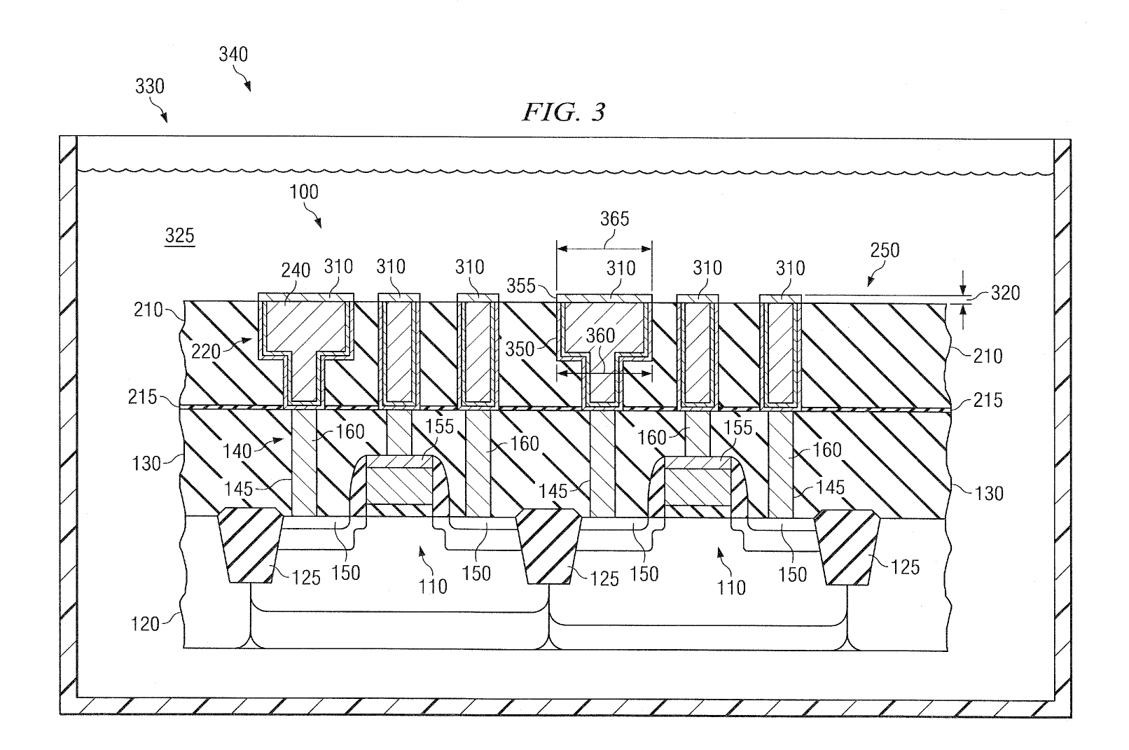

FIG. 3 shows the device 100 while depositing a metal cap layer 310 on the interconnect structure 220. Although the example shows in FIG. 3, the metal cap layer 310 formed on the single or dual damascene interconnect structure 220 in the IDL 210, in other embodiments, metal cap layers can be formed on interconnect structures located in other IDLs (not shown) or on the contacts 140 in the PMD layer 130.

Some embodiments of the metal cap layer 310 include cobalt and one or more of phosphorus, boron, tungsten, or molybdenum. E.g., the metal cap layer 310 can include a cobalt-tungsten-phosphorus alloy or a cobalt-phosphorus alloy. In some cases a cobalt and phosphorus-containing cap layer 310 is deposited on each of copper interconnect structures 220 using an electroless deposition process. The electroless deposition process can include placing the substrate 120 having the interconnect structure 220 thereon into an electroless deposition solution 325 (e.g., a bath solution) for a period sufficient to deposit a desired thickness 320 of the metal cap layer 310.

In some cases the electroless deposition process is performed in a first station 330 (e.g., a deposition bath station) of a system 340 (e.g., an electroless deposition system) for manufacturing semiconductor devices, such as the example device 100. E.g., the first station 330 can be configured to perform an electroless deposition process to form the metal cap layers 310 on exposed surface 250 of the interconnect structures 220 of the substrate 120.

An advantage of using electroless deposition is that the metal cap layers 310 are formed exclusively on the surface 250 of the interconnect structures 220, thereby eliminating the need to perform additional steps to remove the metal cap material from elsewhere on the IDL 210. For instance, in some cases a surface perimeter 350 of the metal cap layer 310 is substantially the same as a perimeter 355 of the interconnect structures 220. E.g., consider when a length 360 of the interconnect structure equals about 30 microns. In some embodiments a length 365 of the metal cap layer 310 equals about 30 microns±1 percent.

Some embodiments of the electroless deposition solution 325 comprise an aqueous solution of metal ions, complexing agents, and reducing agents. An example electroless deposition solution 325 includes an aqueous solution having cobalt sulfate, tungsten, a conventional complexing agent, and a conventional reducing agent. An example electroless deposition process includes exposing a silicon wafer substrate 120 with copper interconnect structures 220 thereon to such a solution 325 to produce a metal cap layer 310 to the desired thickness 320.

In some cases, the sources of phosphorous or boron in the metal cap layer 310 are from the reducing agents (or decomposition products of reducing agents) added to an electroless deposition solution (e.g., deposition bath). E.g., embodiments of the electroless deposition solution can include one or more of sodium hypophosphite, hypophosphorous acid and dimethylamine borane.

The presence of phosphorous or boron in the metal cap layer 310 favorable alters the layer's 310 structure so as to be a more effective electro-migration barrier. While not limiting the scope of the disclosure by theoretical considerations, it believed that phosphorous or boron cause the metal cap layer 310 to have a substantially amorphous structure (e.g., no distinct peaks in a x-ray diffraction spectrum of the metal cap layer). An amorphous structure is desirable because it is more difficult for atoms of the interconnect structure 220 to electro-migrate through metal cap layers 310 having an amorphous structure, than a crystalline structure.

The inclusion of tungsten or molybdenum in the metal cap layers 310 also advantageously improves the layer's 310 ability to deter electro-migration. In some embodiments, the metal cap layer 310 can have a substantially amorphous structure with crystalline structures (e.g., microcrystalline structures) therein. Atoms of the interconnect structure 220 (e.g., copper) can electro-migrate through boundaries (e.g., grain boundaries) between such crystals. While not limiting the scope of the disclosure by theoretical considerations, it is believed that tungsten or molybdenum can segregate at such boundaries and thereby block the diffusion of electro-migration of atoms from the interconnect structure 220. It is further believed that phosphorous or boron can perform a similar function when the metal cap layer 310 has such crystal grain boundaries.

If the goal were to optimize the formation of a magnetic media (e.g., a hard disk media), then it would be counter-intuitive to include species that are not as readily magnetized (e.g., phosphorous, boron, tungsten or molybdenum) as well as cobalt. The inclusion of such species, however, is important, and in some cases critical, to the function of the metal cap layer 310 as an electro-migration barrier. Embodiments of the metal cap layers 310 can include about 1 to 3 weight percent (wt %) phosphorous, boron, or mixtures thereof. Embodiments of the metal cap layers 310 can also include up to about 2 wt % tungsten, molybdenum or both. In some cases, however, it is also desirable to limit the inclusion of such species that are not as readily magnetized as cobalt, because they could make it difficult to measure the magnetic property of the metal cap layer 310. E.g., in some cases, the total amount of phosphorous, boron, tungsten or molybdenum in the metal cap layer is less than about 10 wt %.

It is also important, and in some cases critical, for the metal cap layer 310 to have a thickness 320 that is conducive to its function as an electro-migration barrier. E.g., in some embodiments, the metal cap layer 310 has a thickness 320 of about 8 to 12 nm. Fabricating too thick of a metal cap layer 310 wastes material and unnecessarily lengthens the duration of the metal cap layer fabrication process. Fabricating too thin of a metal cap layer 310 tends to increase the crystallinity of the metal cap layer, thereby making the layer a less effective electro-migration barrier.

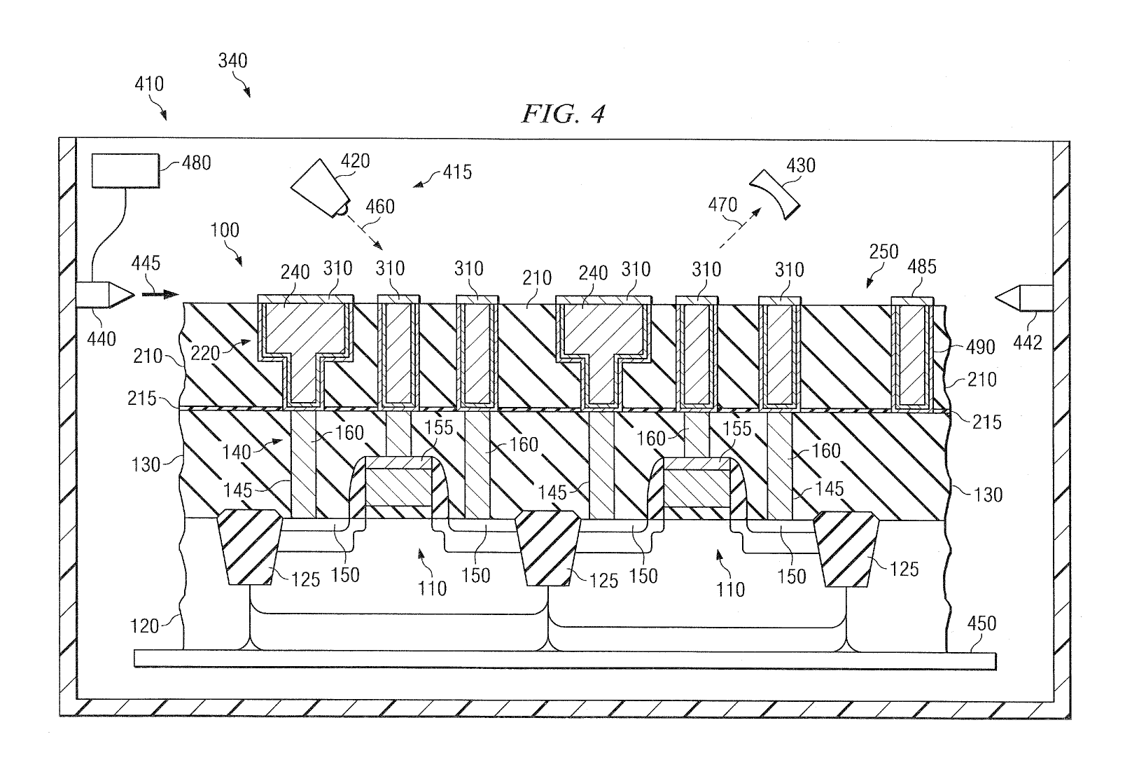

FIG. 4 shows a plan view of the device 100 while measuring a magnetic property of the metal cap layers 310. In some cases, after depositing the metal cap layers 310, the substrate 120 is transferred from the first station 330 (FIG. 3) to a second station 410 of the system 340. The second station 410 can be configured to detect defects in the metal cap layers 310. E.g., the second station 410 can be or include a magnetometer 415 such as a Kerr magnetometer. U.S. Pat. No. 6,501,269 to Vajda (“Vajda”) presents several example magnetometer configurations are capable of measuring magnetic property of the metal cap layer 310. However, other types of magnetometers capable of measuring magnetic property of the metal cap layer 310 could also be used.

Some embodiments of the second station 410 can include at least one polarized light emitter 420 (e.g., a laser), at least one polarized light detector 430, conductive poles 440, 442 configured to generate a magnetic field 445 across the substrate's surface 250 (e.g., parallel or orthogonal to the surface 250) of the substrate 120 having the metal cap layers 310 thereon. The second station 410 can also include a stage 450 that is configured to position the substrate's 120 surface 250 in an emitted light path 460 of the emitter 420 such that that reflected polarized light 470 is receivable by the detector 430. The second station 410 can further include a control module 480 configured to adjust the magnetic field during emission and detection of polarized light 460, 470, such as disclosed in Vajda, incorporated by reference in its entirety. E.g., measuring the magnetic property can include reflecting a beam of polarized light 470 off the interconnect structures 220, during and following the application of the magnetic field 445.

In some cases the magnetic property of the metal cap layers 310 corresponds to one or more parameters related to the magneto-optic Kerr effect. E.g., magnetic property can include one or more of a remnant magnetization (e.g., magnetization of the layer 310 at zero applied magnetic field 445), a coercive force (e.g., the magnetizing force necessary to remove residual magnetism from the layer 310) or Kerr rotation (e.g., a change in the polarization state of the reflected light 470 reflected from the layer 310 compared to the in-coming emitted light 460).

In some cases, measuring the magnetic property of the metal cap layers 310 includes reflecting a beam of the polarized light 470 off of a test metal cap layer 485. The substrate 120 can further include alignment markers to facilitate positioning of the substrate 120 such that the polarized light beam 470 reflects off of the test metal cap layer 485. The test metal cap layer 485 can be made in the same manner and at the same time as the metal cap layer 310 described in the context of FIG. 3. The test metal cap layer 485 can be formed on selected active interconnect structures 220 that are part of an operational circuit of the device 100. Alternatively, as depicted in FIG. 4, the test metal cap layer 485 can be formed on one or more dummy interconnect structures 490 (e.g., dummy contacts or vias) that are not part of an operational circuit of the device 100. To facilitate the detection of unwanted variations in properties of the metal cap layer 310 between substrates 120, it is desirable for the test metal cap layer 485 to form the same pattern and be in the same location for all of the substrates 120 that are measured.

In other cases, measuring the magnetic property of the metal cap layers 310 includes rotating the substrate 120 while reflecting the beam of polarized light 470 off of the metal cap layer 310. E.g., the substrate 120 can be rotated in the same plane as depicted in FIG. 4 at a speed sufficient to provide an averaging of the reflected polarized light 470 reflected from different regions of the substrate's surface 250.

During or after measuring the measured magnetic property, the measured magnetic property can be compared to a target magnetic property. E.g., when the measured magnetic property is a remnant magnetization of cobalt and phosphorus-containing cap layers 310, then the remnant magnetization can be compared to a target remnant magnetization. In some cases, the magnetic property (e.g., target remnant magnetization) can be an average measured from previously measured substrates 120 known to have acceptably performing metal cap layers 310.

Consider the case when the measured magnetic property differs from the target magnetic property by a predefined amount (e.g., ±about 10 percent or about 2 standard deviations from an average target magnetic property). In such cases, one or both the process for forming the interconnect structure 220 or the process for forming the metal cap layer 310 can be altered. The choice as to which of these processes to alter, and what to alter in the process, is guided by the type magnetic property measured and the how this differs from the target magnetic property.

E.g., in some cases, the magnetic property can reflect changes in the thickness 320 of the metal cap layer 310. E.g., consider two metal cap layer 310 which during the electroless deposition process are formed to thicknesses 320 (FIG. 3) of about 90 nm and about 150 nm, respectively. The remnant magnetism of these two metal cap layers 310 can differ by about 50 percent (e.g., about 5 and 7.5 milli-electromagnetic units per centimeter squared, memu/cm², respectively). Thus in some embodiments, when the remnant magnetism of the metal cap layers 310 differs from a remnant magnetism by a predefined amount, the second station 410 can be configured to signal a system operator that a defect has been detected.

In other cases, the magnetic property reflects changes in the composition of the electroless deposition solution 325 (FIG. 3) as the solution's 325 composition ages. E.g., consider two cobalt-phosphorus alloy metal cap layers 310 which are formed in the same solution 325, but at about 0 and 8 hours, respectively, after preparing the solution. The remnant magnetism of the second of these two layers 310 can be about 50 percent of the first layer 310 (e.g., about 9 and 5 memu/cm², for the first and second layers 310, respectively), reflecting a decrease in the phosphorus content of the second compared to first layer (e.g., about 2.5 and 1 wt % for the for the first and second layers 310, respectively).

In cases when the remnant magnetism of the metal cap layers 310 differs from a remnant magnetism by a predefined amount, the second station 410 can be configured to signal a system operator that a defect has been detected. The operator may then alter one or both of interconnect structure formation process or the metal cap layer deposition process.

E.g. when the interconnect structure formation process includes a damascene process, the process can be altered by including a cleaning process configured to remove any residual corrosion inhibitor left on the interconnect structures 220 following the CMP step. Residual quantities of corrosion inhibitors, such as BTA, could deter the formation of the metal cap layer 310. In some cases the cleaning process includes exposing the surface 250 of the interconnect structures 220 to a hydrogen-containing plasma or to a thermal anneal.

E.g., the metal cap layer deposition process can be altered by changing the concentration of one or more chemicals in an electroless deposition solution or changing a duration of the deposition process. For instance, a phosphorus-containing reducing agent can be added to the solution 325 (FIG. 3) as this component is depleted with successive depositions steps, as suggested by changes in the measured magnetic property. Or, a substrate 120 can be maintained in the solution 325 for longer periods if the thickness 320 of the metal cap layer 310 is decreasing with successive depositions steps, as suggested by changes in the measured magnetic property.

In some instances, the detection of metal cap layers 310 with non-target magnetic properties may cause the operator of the system 340 to discard the substrate 120. E.g., the second station 410 can be configured to reject the substrate 120 if the metal cap layer's 310 magnetic properties are out of a predefined range. In other instances, the substrate 120 subjected to a rework process. E.g., the second station 410 can be configured to transfer the substrate 120 to an early point in the manufacturing process. E.g., one or more of the metal cap layer 310, interconnect structures 220 or IDL 210 can be stripped off and re-formed such as disclosed above in the context of FIGS. 2-3.

Consider the alternative case when the measured magnetic property does not differ from the target magnetic property by a predefined amount. E.g., a remnant magnetization of the metal cap layers 310 do not differ from a target remnant magnetization by less than about 10 percent. In such cases, the manufacture of the device 100 can continue until the completion of the device 100. E.g., the second station 410 can be configured to transfer the semiconductor substrate 120 to another station of the system 340, or a different system, that carries out a next step in the device's 100 manufacturing process. Transfer to the next step is contingent whether the magnetic property of the metal cap layers 310 measured by the second station 410 is within a predefined range.

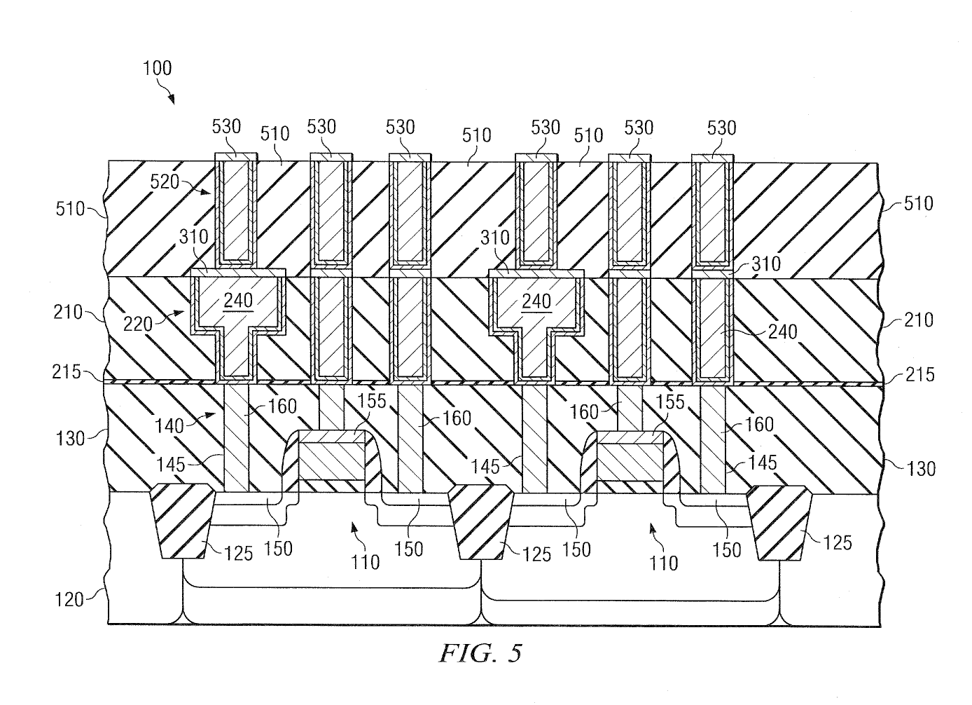

FIG. 5 shows the device 100 after depositing an additional insulating layer, e.g., a second IDL 510, on the insulating layers (e.g., the PMD layer 130 and IDL 210). As illustrated, the metal cap layers 310 are covered by the second IDL 510. FIG. 5 also shows the device after forming second interconnect structures 520 in the second IDL 510 and forming second metal cap layers 530 on the second interconnect structures 520. The processes for forming the second IDL 510, the second interconnect structure 520 and the metal cap layers 530 can be same as discussed above in the context of FIGS. 1-3. Additionally, the magnetic properties of the second metal cap layers 530 can be assessed by the same process as described in the context of FIG. 4. These steps can be continued to form additional IDLs, interconnects and metal cap layers until the device's 100 fabrication is completed.

FIG. 5 illustrates another embodiment of the disclosure the semiconductor device 100 itself. The device 100 can be manufactured by any of the embodiments of the method described in the context of FIGS. 1-5. The device 100 comprises one or more transistors 110 on or in the semiconductor substrate 120. The device 100 further comprises an IDL 210 on the substrate 120 and over the transistors 110. There are interconnect structures 220 on the IDL 210, and metal cap layers 310 located on the interconnect structures 220 and not on the IDL 210. At lease one of the metal cap layers 310 are formed by a process such as described in the context of FIG. 4. E.g., the metal cap layer's 310 magnetic properties are measured and then compared to a target magnetic property. One or both of the interconnect's 220 or metal cap layer's 310 fabrication processes are altered if the measured magnetic property differs from the target magnetic property by a predefined amount.

Those skilled in the art to which the disclosure relates will appreciate that other and further additions, deletions, substitutions, and modifications may be made to the described example embodiments, without departing from the disclosure.

What is claimed is:

1. A method of manufacturing a semiconductor device, comprising:
forming transistors on or in a semiconductor substrate;
depositing insulating layers on said substrate such that said transistors are covered by said insulating layers;
performing a damascene process to form copper interconnect structures in at least one of said insulating layers;
depositing individual cobalt and phosphorus-containing cap layers on each of said copper interconnect structures using an electroless deposition process;
measuring a remnant magnetization of said cobalt and phosphorus-containing cap layers;
comparing said measured remnant magnetization to a target remnant magnetization; and
altering one or both of said damascene process or said electroless deposition process if said measured remnant magnetization differs from said target remnant magnetization by a predefined amount, or alternatively, depositing an additional insulating layer on said insulating layers if said remnant magnetization does not differ from said target remnant magnetization by said predefined amount.

2. A method of manufacturing a semiconductor device, comprising:
forming an interconnect structure in an insulating layer located on a semiconductor substrate;
depositing a metal cap layer on said interconnect structure;
measuring a magnetic property of said metal cap layer;
comparing said measured magnetic property to a target magnetic property; and
altering one or both of an interconnect structure formation process or a metal cap layer deposition process if said measured magnetic property differs from said target magnetic property by a predefined amount.

3. The method of claim 2, wherein said magnetic property includes one or more of a remnant magnetization, coercive force or Kerr rotation.

4. The method of claim 2, wherein measuring said magnetic property includes reflecting a beam of polarized light off said metal cap layer.

5. The method of claim 2, wherein measuring said magnetic property includes reflecting a beam of polarized light off of a test metal cap layer.

6. The method of claim 2, wherein measuring said magnetic property includes rotating said semiconductor substrate while reflecting a beam of polarized light off said metal cap layer.

7. The method of claim 2, wherein said interconnect structures include single or dual damascene copper interconnects.

8. The method of claim 2, wherein said metal cap layer includes cobalt and one or more of phosphorus, boron, tungsten or molybdenum.

9. The method of claim 2, wherein said metal cap layer includes a cobalt-tungsten-phosphorus alloy or a cobalt-phosphorus alloy.

10. The method of claim 2, wherein altering said interconnect structure formation process includes a cleaning process to remove a corrosion inhibitor from a surface of said interconnect structures.

11. The method of claim 2, wherein altering said metal cap layer deposition process includes changing the concentration of one or more chemicals in an electroless deposition solution, or changing a duration of said deposition process.

12. The method of claim 2, alternatively, includes depositing a second insulating layer on said insulating layer, if said remnant magnetization does not differ from said target remnant magnetization by said predefined amount.

13. The method of claim 2, wherein said substrate is subjected to a rework process, if said remnant magnetization differs from said target remnant magnetization by said predefined amount.

14. A semiconductor device, comprising:
one or more transistors on or in a semiconductor substrate;
an insulating layer on said semiconductor substrate and over said transistors;
interconnect structures in said insulating layer, metal cap layers located on said interconnect structures and not on said insulating layer, wherein at least one of said metal cap layers are formed by a process that includes:
measuring a magnetic property of said metal cap layers;
comparing said measured magnetic property to a target magnetic property; and
altering a damascene process to form said interconnect structures, or alternatively, altering a electroless process to form said metal cap layers, if said measured magnetic property differs from said target magnetic property by a predefined amount.

15. The device of claim 14, wherein said interconnect structures include a tantalum-containing barrier layer and a copper layer, and said metal cap layer includes cobalt and phosphorus.

16. The device of claim 14, wherein said metal cap layer has a substantially amorphous structure.

17. The device of claim 14, wherein said metal cap layer has a thickness of about 8 to 12 nm.

18. A system for manufacturing semiconductor devices, comprising:
a first station configured to perform an electroless deposition process to form metal cap layers on exposed interconnect structures of a semiconductor substrate; and
a second station configured to detect defects in said metal cap layer, said second station including:
at least one polarized light emitter;
at least one polarized light detector;
a stage configured to position a surface of said semiconductor substrate having said metal cap layers thereon in a light path of said emitter such that that reflected polarized light is receivable by said detector;
conductive poles configured to generate a magnetic field across said surface; and
a control module configured to adjust said magnetic field during emission and detection of polarized light,
wherein said semiconductor substrate is transferred to a next step in a device fabrication process if a magnetic property of said metal caps measured by said second stage is within a predefined range, or alternatively, said semiconductor substrate is rejected if said magnetic property is outside of said predefined range.

19. The system of claim 18, wherein said stage is configured to rotate said semiconductor substrate during emission and detection of said polarized light.

20. The system of claim 18, wherein said rejected semiconductor substrate is returned to an early step in said fabrication process and one or more of said earlier steps is modified.
